(19) United States
(12) Patent Application Publication
(10) Pub. No.: US 2024/0405744 A1
(43) Pub. Date: Dec. 5, 2024

(54) ACOUSTIC WAVE DEVICES

(71) Applicant: Sanan Japan Technology Corporation, Tokyo (JP)

(72) Inventors: Yutaka KADOGAWA, Tokyo (JP); Hiroshi NAKAMURA, Tokyo (JP); Shinichi SHIOI, Tokyo (JP)

(73) Assignee: Sanan Japan Technology Corporation, Tokyo (JP)

(21) Appl. No.: 18/677,216

(22) Filed: May 29, 2024

(30) Foreign Application Priority Data
May 30, 2023 (JP) 2023-088591

(51) Int. Cl. H03H 9/08; H03H 3/08; H03H 9/02; H03H 9/05; H03H 9/10; H03H 9/25

(52) U.S. Cl. CPC H03H 9/08; H03H 3/08; H03H 9/02913; H03H 9/059; H03H 9/1085; H03H 9/25

(57) ABSTRACT

An acoustic wave device includes a device chip, a first metal pattern formed on one surface of the device chip and including a pattern configured to form a resonator, a second metal pattern formed on the one surface of the device chip so as to have a predetermined thickness larger than the first metal pattern at any position and including a pattern including a signal input/output terminal, a wiring connecting the signal input/output terminal and the resonator, a wiring connecting a plurality of resonators and a ground wiring, a first roof portion made of resin formed on the second metal pattern, a metal layer within the roof formed on the first roof portion, a second roof portion made of resin formed on the first roof portion, two or more heat dissipation solder bumps formed by a heat dissipation passage hole passing through the second roof portion.

### CROSS-REFERENCE TO RELATED APPLICATION(S)

This application claims priority to Japanese Application No. 2023-088591, filed May 30, 2023, which are incorporated herein by reference, in their entirety, for any purpose.

### BACKGROUND OF THE INVENTION

### Field of the Invention

The present disclosure relates to improvements in acoustic wave devices suitable for use as a frequency filter or the like in such as mobile communication device.

An acoustic wave (Surface Acoustic Wave/SAW) device including WLP (Wafer Level Package) structure has a structure disclosed in Patent Document 1 (JP2002-217673). In the Patent Document 1, a cover is provided on one surface of a device chip, and IDT electrodes formed on the one surface are positioned in an inner space formed by the cover.

Here, although heat is generated in the device chip by an input of a signal to the acoustic wave device, a piezoelectric body constituting the device chip has low thermal conductivity and poor heat dissipation. The thermal conductivity of lithium tantalate or lithium niobate used as a piezoelectric material is about 4 to 6 W/mK.

### SUMMARY OF THE INVENTION

Some examples described herein may mainly solve the problem in the acoustic wave device that includes such as WLP structure to provide new structure capable of rationally improving heat dissipation of a device chip constituting the acoustic wave device.

In some examples, an acoustic wave device includes a device chip, a first metal pattern formed on one surface of the device chip and including a pattern to be a resonator, a second metal pattern formed on the one surface of the device chip so as to have a predetermined thickness larger than the first metal pattern at any position and including a pattern including a signal input/output terminal, a wiring connecting the signal input/output terminal and the resonator, a wiring connecting the plurality of resonators and a ground wiring, a first roof portion made of formed on the second metal pattern and cooperating with the one surface of the device chip and the second metal pattern to form a sealed space of the resonator, a metal layer within the roof formed on the first roof portion, a second roof portion made of resin formed on the first roof portion so as to position the metal layer within the roof between the first roof portion, two or more heat dissipation solder bumps formed by a heat dissipation passage hole passing through the second roof portion and including an inner end portion joined to the roof inner metal layer and an outer end portion protruding from the second roof portion.

### BRIEF DESCRIPTION OF THE DRAWING

FIG. 1 is a cross-sectional view of an acoustic wave device (in a first example) according to an embodiment of the present disclosure, and the first example is shown as a cross-sectional view of taken along line B-B in FIG. 2.

FIG. 2 is a cross-sectional view taken along line A-A in FIG. 1.

FIG. 3 is a cross-sectional view taken along line C-C in FIG. 2.

FIG. 4 illustrates an example of a resonator formed on a device chip according to the first example.

FIG. 5 illustrates an example of a circuit formed on the device chip of the first example.

FIG. 6 is a cross-sectional view showing a main part of the manufacturing step of the first example.

FIG. 7 is a cross-sectional view showing a main part of the manufacturing step of the first example.

FIG. 8 is a cross-sectional view showing a main part of the manufacturing step of the first example.

FIG. 9 is a cross-sectional view showing a main part of the manufacturing step of the first example.

FIG. 10 is a cross-sectional view showing a main part of the manufacturing step of the first example.

FIG. 11 is a cross-sectional view showing a main part of the manufacturing step of the first example.

FIG. 12 is a cross-sectional view of a second example of an acoustic wave device in which a part of the configuration is different from that of the first example.

FIG. 13 is a cross-sectional view showing a main part of the manufacturing step of the second example.

FIG. 14 is a cross-sectional view showing a main part of the manufacturing step of the second example.

FIG. 15 is a cross-sectional view showing a main part of the manufacturing step of the second example.

FIG. 16 is a cross-sectional view showing a main part of the manufacturing step of the second example.

FIG. 17 is a cross-sectional view of a third example of the acoustic wave device in which a part of the configuration is different from that of the first example, and the third example is shown as cross-sectional view of taken along line E-E in FIG. 18.

FIG. 18 is a cross-sectional view taken along line D-D in FIG. 17.

FIG. 19 is a cross-sectional view of a fourth example of the acoustic wave device in which a part of the configuration is different from that of the first example, and the fourth example is shown from the same direction as that of FIG. 3.

### DETAILED DESCRIPTION

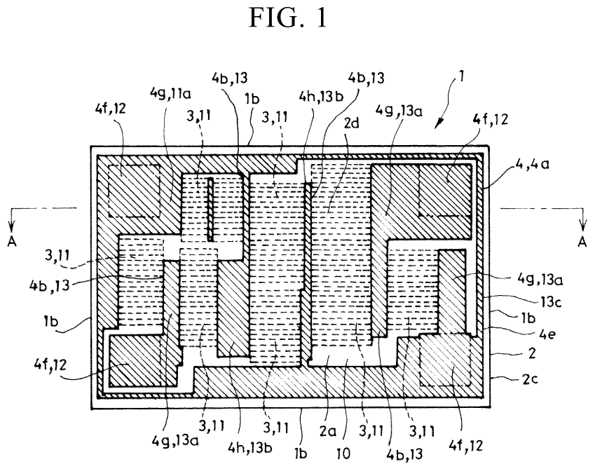

Hereinafter, the exemplary embodiment will be described with reference to FIGS. 1 to 19. An acoustic wave device 1 according to this embodiment is suitable for use as a frequency filter or the like in such as mobile communication device.

The acoustic wave device 1 includes a device chip 2, a first metal pattern 3, a second metal pattern 4, a first roof portion 5, a metal layer within the roof 7, a second roof portion 6, an external connecting solder bump 8, and a heat dissipating solder bump 9.

The first metal pattern 3 is formed on one surface 2a of the device chip 2. The second metal pattern 4 having a thickness of not less than a thickness of the first metal pattern 3 is formed on the one surface 2a of the device chip 2.

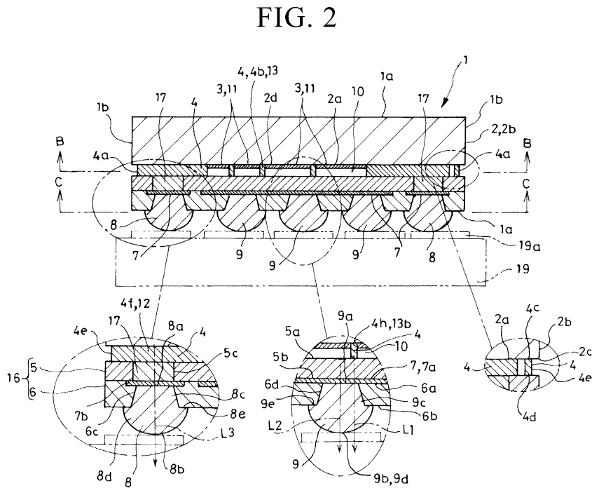

An outer portion 4a (shown in FIG. 1 and FIG. 2) of the second metal pattern 4 formed on an outer edge portion 2c of the device chip 2, in which the one surface 2a and a side surface 2b of the device chip 2 are in contact with each other, surrounds the inner side of the outer edge portion 2c on the one surface 2a of the device chip 2 as a main surface portion 2d of the device chip 2 (a surface portion exhibiting a function as the acoustic wave device 1). And a partitioning wall-shaped inner portion 4b formed in an area other than the area where the first metal pattern 3 is formed on the main surface portion 2d mainly functions as the wire 13.

The second metal pattern 4 includes the outer portion 4a and the partitioning wall-shaped inner portion 4b.

A part of the inner portion 4b of the second metal pattern 4 is formed to be overlapped on a part of the first metal pattern 3, can be formed to be connected to the first metal pattern 3.

The first roof portion 5 is supported on the second metal pattern 4 with its inner surface 5a fixed to a second end 4d opposed to a first end 4c fixed to the one surface 2a of the device chip 2 in the second metal pattern 4.

On one surface 2a of the device chip 2, a sealed space 10 (cavity, hollow-structure portion) is formed by the main surface portion 2d, the outer portion 4a of the second metal pattern 4, and the first roof portion 5, and a resonator 11 that will be described later and is formed by the first metal pattern 3 is disposed in the sealed space 10.

Typically, the device chip 2 is configured to be a quadrangular plate shape (a rectangle as the example of the drawings) having a side of 0.5 mm to 1 mm and a thickness of 0.15 mm to 0.2 mm.

Typically, the first metal pattern 3 is configured to have a thickness of 0.1 m to 0.5 μm (a height of the first metal pattern 3 with respect to the one surface 2a of the device chip 2) in a direction perpendicular to the one surface 2a of the device chip 2.

Typically, the second metal pattern 4 is configured to have a thickness of 3 μm to 5 μm in a direction perpendicular to the one surface 2a of the device chip 2.

Typically, the first roof portion 5 is configured to have a thickness of 15 μm to 35 μm.

Further, the second roof portion 6, which will be described later, formed on the first roof portion 5 to sandwich the later-described metal layer within the roof 7, is configured to have a thickness of 15 μm to 35 μm.

The acoustic wave device 1 includes these components typically has a thickness of about 0.25 mm to 0.35 mm.

The acoustic wave device 1 has a square or rectangular contour when viewed from a direction perpendicular to the one surface 2a of the device chip 2.

That is, the acoustic wave device 1 is a flat hexahedral shape having two quadrangular shaped surfaces 1a and four side surfaces 1b extending between the two quadrangular shaped surfaces 1a.

In the drawings, the thicknesses of the constituent elements are exaggerated so that the configuration of the acoustic wave device 1 can be easily understood.

The device chip 2 has a function of propagating an elastic wave. Typically, lithium tantalate or lithium niobate is used as a piezoelectric body in the device chip 2, and the device chip 2 may be configured by laminating sapphire, silicon, alumina, spinel, quartz crystal, glass, or the like on the piezoelectric body.

The first metal pattern 3 is formed on the one surface 2a of the device chip 2 so as to have a predetermined thickness at any position and includes a pattern to be the resonator 11.

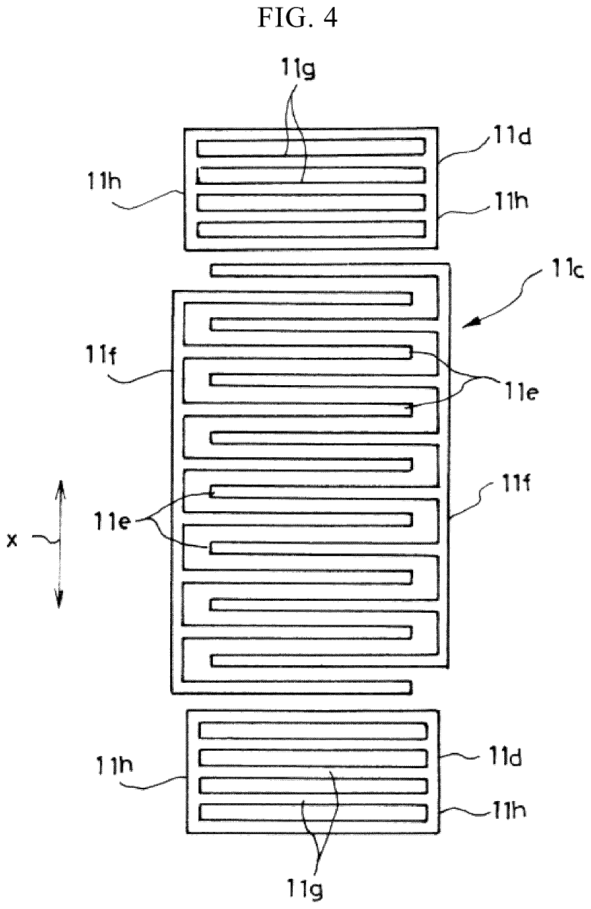

FIG. 4 illustrates an example of the resonator 11 formed on a device chip according to the first example. The resonator 11 has an IDT electrode 11c and a reflector 11d formed so as to sandwich the IDT electrode 11c. IDT electrode 11c is formed of electrode pairs, and each electrode pair is formed by connecting a plurality of electrode fingers 11e arranged in parallel so as to cross the length direction in a propagation direction x of the acoustic wave by a busbar 11f at one end thereof. The reflector 11d is formed by connecting ends of a plurality of electrode fingers 11g arranged in parallel so as to cross the length direction in the propagation direction x of the acoustic wave by a busbar 11h.

The first metal pattern 3 is typically configured of a conductive metal film formed by a photolithography technique.

As shown in FIG. 1 and FIG. 2, the second metal pattern 4 is formed on the one surface 2a of the device chip 2 so as to have a predetermined thickness larger than the first metal pattern 3 at any position, and includes a pattern that configured of a signal input/output terminal 12, a wiring 13a connecting the signal input/output terminal 12 and the resonator 11, a wiring 13b connecting the plurality of resonators 11, and a ground wiring 13c.

In the example of the drawings, the outer part 4a of the second metal pattern 4 includes an outer wall surface 4e that is slightly inside the outer edge 2c of the device chip 2 and substantially parallel to the outer edge 2c. The inner side of the outer wall surface 4e is the main surface portion 2d.

In the example of the drawings, a first portion 4f of the second metal pattern 4 functions as the signal input/output terminal 12 is formed by the second metal pattern 4 at each of the four corners of the device chip 2.

A second portion 4g of the second metal pattern 4 functions as the wiring 13a is formed between the first portion 4f and the resonator 11. A third portion 4h of the second metal pattern 4 functions as the wiring 13b is formed between adjacent resonators 11. The second metal pattern 4 is also typically formed of a conductive metal film formed by the photolithography technique.

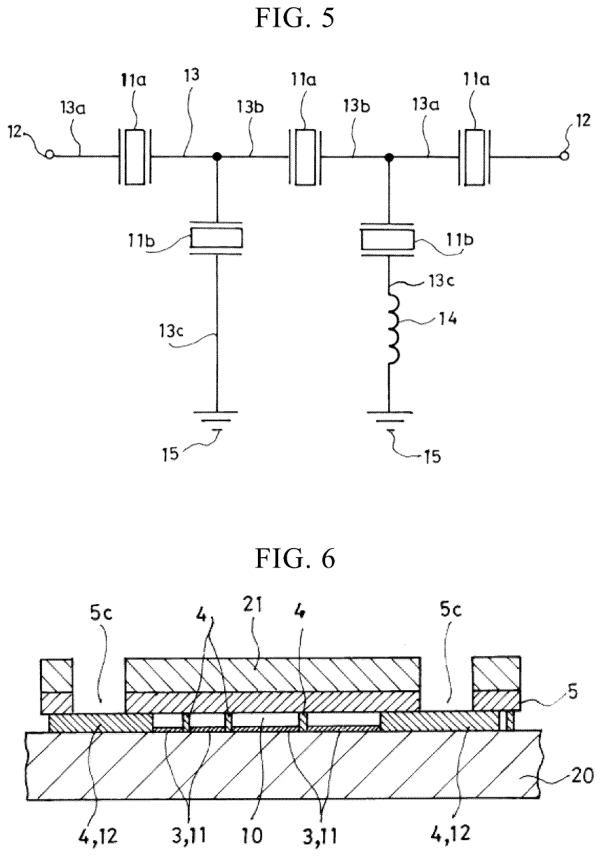

FIG. 5 illustrates an example of a circuit formed on the device chip of the first example. FIG. 5 shows a concept of an example of a circuit provided on one device chip 2 by the first metal pattern 3 and the second metal pattern 4. Reference character 11a refers a resonator 11 connected in series between the signal input/output terminals 12, reference character 11b refers a resonator 11 connected in parallel between the signal input/output terminals 12, reference character 14 refers an inductor, and reference character 15 refers a ground. The quantity and arrangement of the resonators 11 are changed as necessary. That is, the ladder filter is configured by the circuit of FIG. 5.

In the example of the drawings, the ground wiring 13c connected to the ground 15 in the above-described circuit is arranged so as to surround the first metal pattern 3, the signal input/output terminal 12, the wiring 13a connecting the signal input/output terminal 12 and the resonator 11, and the wiring 13b connecting the plurality of resonators 11 to each other.

The ground wiring 13c is the wiring 13 connecting the resonator 11 and the ground 15 in the above-described circuit without interposing another resonator 11 therebetween. In the example of the drawings, as shown in FIG. 1, the outer part 4a of the second metal pattern 4 functions as the ground wiring 13c.

In addition, at least a part of the metal layer within the roof 7 that will be described later, may function as the inductor 14. In this case, one end of the inductor 14 is electrically connected to a wire connecting the resonator 11 and the inductor 14 through a wiring body 17 and a via 5c passing through the first roof portion 5. The other end of the inductor 14 is connected to a portion (not shown in the drawings) of an accompanying portion 7b of the metal layer within the roof 7 that is connected to the ground 15.

The first roof portion 5 is made of an insulating resin. The first roof portion 5 is formed on the second metal pattern 4, and cooperates to form the sealed space 10 of the resonator 11 with the one surface 2a of the device chip 2 and the second metal pattern 4.

The first roof portion 5 is preferably made of a non-photosensitive resin and has a higher thermal conductivity than that of the resin constituting the second roof portion 6. As such a resin, a resin in which fillers made of a material having a high thermal conductivity are contained in an amount of 70 weight % to 90 weight % with respect to a resin serving as a base material is used. Such fillers are typically configured as granules around 10 μm in diameter.

Specifically, as a resin constituting the first roof portion 5, an epoxy resin containing a filler or a phenolic resin containing a filler can be used. Typically, alumina, aluminum nitride, or powdered diamond may be used as the filler.

The first roof portion 5 has the inner surface 5a substantially parallel to the one surface 2a of the device tip 2 and an outer surface 5b opposite thereto. In the example of the drawings, the first roof portion 5 is shaped in the form of a plate having substantially the same shape and size as the device chip 2. A gap corresponding to the thickness of the second metal pattern 4 is formed between the inner surface 5a of the first roof portion 5 and the one surface 2a of the device chip 2, and the gap is hermetically sealed by the outer portion 4a of the second metal pattern 4 to form the sealed space 10.

The metal layer within the roof 7 is formed on the outer surface 5b of the first roof portion 5.

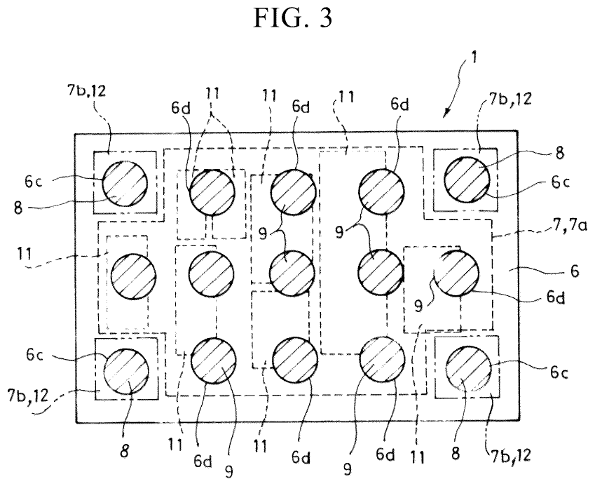

As shown in FIG. 3, the metal layer within the roof 7 includes a main portion 7a formed on the forming region of the resonator 11 and having a size substantially covering the entire forming region, and the accompanying portion 7b formed on the signal input/output terminal 12.
In the example of the drawings, the main portion 7a and the accompanying portion 7b are separated from each other. In such a circuit shown in FIG. 5, a part of the accompanying portion 7b is the inductor 14. Further, the metal layer within the roof 7 is configured of thinner film than the first roof portion 5 and the second roof portion 6. The metal layer within the roof 7 is typically formed by lift-off.

The second roof portion 6 is formed on the first roof portion 5 so as to position a portion of the metal layer within the roof 7 between the first roof portion 5 and the second roof portion 6. The second roof portion 6 is made of an insulating resin.

The second roof portion 6 is preferably made of a photosensitive resin. The second roof portion 6 is formed so as to include an inner surface 6a fixed to the outer surface 5b of the first roof portion 5 and an outer surface 6b opposed thereto and to cover the entire outer surface 5b of the first roof portion 5 and the metal layer within the roof 7.

A roof 16 is formed from three parties: the first roof portion 5, the metal layer within the roof 7, and the second roof portion 6.

The thickness of the first roof portion 5 is preferably smaller than the thickness of the second roof portion 6. This can ensure the rigidity of the roof 16 by increasing the thickness of the roof 16 and improve heat dissipation efficiency by minimizing a distance between one surface of the device chip and the metal layer within the roof 7 through a first path L1 and a second path L2 that are described later.

In the first example shown in FIG. 1 to FIG. 5, the accompanying portion 7b as a part of the metal layer within the roof 7 is electrically connected to the signal input/output terminal 12 through the via 5c passing through the first roof portion 5.

In the first example, the via 5c is formed in the first roof part 5 so that the signal input/output terminal 12 is positioned at the bottom of the hole, and the wiring body 17 formed in the via 5c is connected to an accompanying portion 7b positioned on the via 5c.

In the first example, the external connecting solder bump 8 is formed by using a connecting passing hole 6c passing through the second roof portion 6, and includes an inner end 8a joined to the accompanying portion 7b as the part of the metal layer within the roof 7 and an outer end 8b protruding from the second roof portion 6.

The connecting passing hole 6c is formed in the second roof portion 6 just above the accompanying portion 7b of the metal layer within the roof 7, and the bottom of the connecting passing hole 6c corresponds to the accompanying portion 7b.

In the example of the drawings, the diameter of the connecting passing hole 6c is configured to gradually decrease toward the inner surface 6a of the second roof portion 6, and the hole wall is inclined.

The external connecting solder bumps 8 includes a shaft portion 8c positioned in the connecting passing hole 6c and having a shape that is complementary to the connecting passing hole 6c, and a head portion 8d positioned on the outer surface 6b of the second roof portion 6. Between the shaft portion 8c and head portion 8d, a circumferential jaw 8e fixed to the outer surface 6b of the second roof portion 6 is formed. The head portion 8d is a hemispherical shape and forms the outer end 8b.

In a second example shown in FIG. 12, the external connecting solder bump 8 is formed by using a connecting passing hole 18 passing through the first roof portion 5 and the second roof portion 6, and has a configuration including an inner end 8a joined to the signal input/output terminal 12 and an outer end 8b protruding from the second roof portion 6.

In the second example, the circuit formed in the device chip 2 and the outside thereof can be connected by the external connecting solder bump 8 without the metal layer within the roof 7.

The heat dissipating solder bumps 9 is formed by using a heat dissipating passing hole 6d passing through the second roof portion 6, and includes an inner end 9a joined to the metal layer within the roof 7 an outer end 9b protruding from the second roof portion 6.

The heat dissipating passing hole 6d includes an opening on an outer surface 6b of the second roof part 6, and disposes the metal layer within the roof 7 at a bottom of the heat dissipating passing hole 6d.

In the example of the drawings, the diameter of the heat dissipating passing hole 6d is configured to gradually decrease toward the inner surface 6a of the second roof portion 6, and the hole wall is inclined.

The heat dissipating solder bumps 9 includes a shaft portion 9c positioned in the heat dissipating passing hole 6d and having a shape that is complementary to the heat dissipating passing hole 6d, and a head portion 9d positioned on the outer surface 6b of the second roof portion 6. Between the shaft portion 9c and head portion 9d, a circumferential jaw 9e fixed to the outer surface 6b of the second roof portion 6 is formed. The head portion 9d is a hemispherical shape and forms the outer end 9b.

The acoustic wave device includes the two or more heat dissipating solder bumps 9.

Further, as shown in FIG. 3, the heat dissipating solder bumps 9 are formed on the forming region of the resonator 11 when viewed from a direction perpendicular to the one surface 2a of the device chip 2. In the example of the drawings, all of the two or more heat dissipating solder bumps 9 are formed so that at least a portion thereof is positioned on the forming region of the resonator 11.

Firstly, the acoustic wave device 1 according to an example implementation according to the present disclosure contributes to a demand for a reducing-height device of this type by minimizing the thickness of the acoustic wave device 1 with forming the sealed space 10 of the resonator 11 by the second metal pattern 4 and the first roof portion 5.

Second, the heat generated in the device chip 2 can be efficiently dissipated to the outside through the linear first path L1 (shown in FIG. 2) passing the second metal pattern 4, the first roof portion 5, the metal layer within the roof 7, and the heat dissipating solder bumps 9. When the first roof part 5 is made of a resin having a high thermal conductivity, the heat dissipation efficiency through the first path L1 is improved.

Third, the heat transferred to the first roof portion 5 through the second metal pattern 4 can be efficiently dissipated to the outside through the second path L2 (shown in FIG. 2) passing the first roof portion 5, the metal layer within the roof 7, and the heat dissipating solder bumps 9. The first roof part 5 made of a resin having a high thermal conductivity improves the heat dissipation efficiency through the second path L2.

Fourth, the heat generated in the device chip 2 can be efficiently dissipated to the outside through a third path L3 (shown in FIG. 2) passing the second metal pattern 4 and the external connecting solder bumps 8.

Typically, as shown in FIG. 2, the acoustic wave device 1 is mounted on the module substrate 19 by fixing the external connecting solder bump 8 and the heat dissipating solder bump 9 to a metallic connecting portion 19a formed on the module substrate 19 by ultrasonic bonding, and forming a module. The heat generated in the device chip 2 is thus dissipated to the module substrate 19 side on which the acoustic wave device 1 is mounted.

The acoustic wave device 1 according to the first example can be appropriately and rationally produced by a producing method including the following steps.

First, the first metal pattern 3 is formed on one surface of the wafer 20 to be the device chip 2 (first step/drawing is omitted).

Next, the second metal pattern 4 is formed on the one surface of the wafer 20 to be the device chip 2 (second step/drawing is omitted).

Next, the first roof portion 5 is formed on the one surface of the wafer 20 to be the device chip 2 (third step/drawing is omitted).

The first roof portion 5 may be formed by laminating a resin-made planar body (film) on the one surface of the wafer 20 and integrating them.
It is possible to reliably establish the first path L1 because pressurizing the first roof portion 5 after forming the first roof portion 5 in this way enable integrating the inner surface 5a and the second metal pattern 4 of the first roof portion 5 without a gap.

Next, a resist 21 for forming the via 5c is formed on the first roof portion 5 formed in the third step, and the via 5c is formed by removing a part of the first roof portion 5 by chemical treatment using the resist 21. (fourth step/FIG. 6).

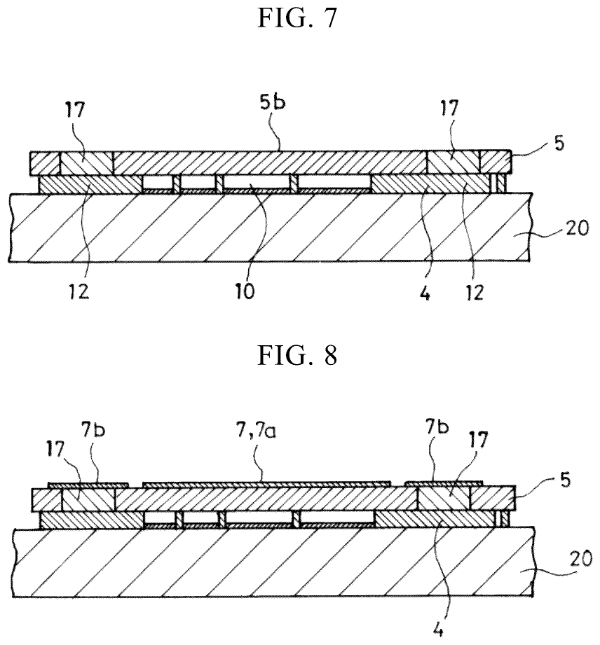

Next, after the resist 21 formed in the fourth step is removed, the wiring body 17 is formed by filling the via 5c with a metal (fifth step/FIG. 7). The wiring body 17 is typically formed by electroless metal plating. The wiring body 17 is formed so that one end thereof is fixed to the signal input/output terminal 12 and the other end thereof opposed thereto is flush with the outer surface 5b of the first roof portion 5.

Then, the main portion 7a and the accompanying portion 7b as the metal layer within the roof 7 are formed on the first roof portion 5 (sixth step/FIG. 8). The metal layer within the roof 7 can typically be formed by lift-off.

Then, the second roof portion 6 is then formed on the first roof portion 5. The second roof portion 6 can be formed by laminating a resin-made planar body (film) on the first roof portion 5 and integrating them. Alternatively, the second roof portion 6 may be formed by applying the resin onto the first roof portion 5.

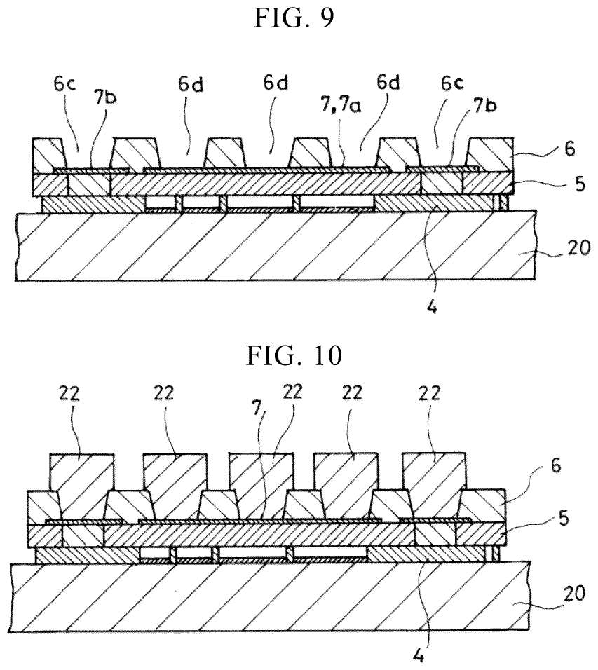

After forming the resin layer to be the second roof portion 6 on the first roof portion 5 in this way, a resist (drawing is omitted) for forming the connecting passing hole 6c and the heat dissipating passing hole 6d is formed thereon, the connecting passing hole 6c and the heat dissipating passing hole 6d are formed by removing a portion of the resin layer to be the second roof portion 6 by this resist (seventh steps/FIG. 9).

Next, the connecting passing hole 6c and the heat dissipating passing hole 6d are coated and filled with the cream-solder 22 typically by a printer (eighth step/FIG. 10).

Reflow process after the eighth step forms the external connecting solder bumps 8 and the heat dissipating solder bump 9 having a height protruding from the outer surface of the second roof portion 6.

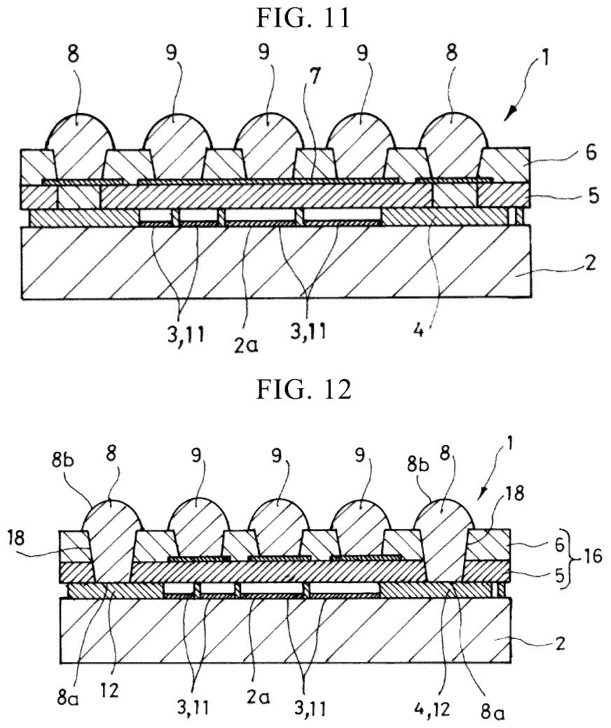

Thereafter, dicing is performed on the wafer 20 to generate the acoustic wave device 1 including the plurality of structures from the wafer 20 (FIG. 11).

Further, the acoustic wave device 1 according to the second example can be appropriately and rationally produced by a producing method including the following steps.

First, the first metal pattern 3 is formed on one surface of the wafer 20 to be the device chip 2 (first step/illustration is omitted).

Next, the second metal pattern 4 is formed on the one surface of the wafer 20 to be the device chip 2 (second step/illustration is omitted).

Next, the first roof portion 5 is formed on the one surface of the wafer 20 to be the device chip 2 (third step/illustration is omitted). The first roof portion 5 may be formed by laminating a resin-made planar body (film) on one surface of the wafer 20 and integrating them.

It is possible to reliably establish the first path L1 because pressurizing the first roof portion 5 after forming the first roof portion 5 in this way enable integrating the inner surface 5a and the second metal pattern 4 of the first roof portion 5 without a gap.

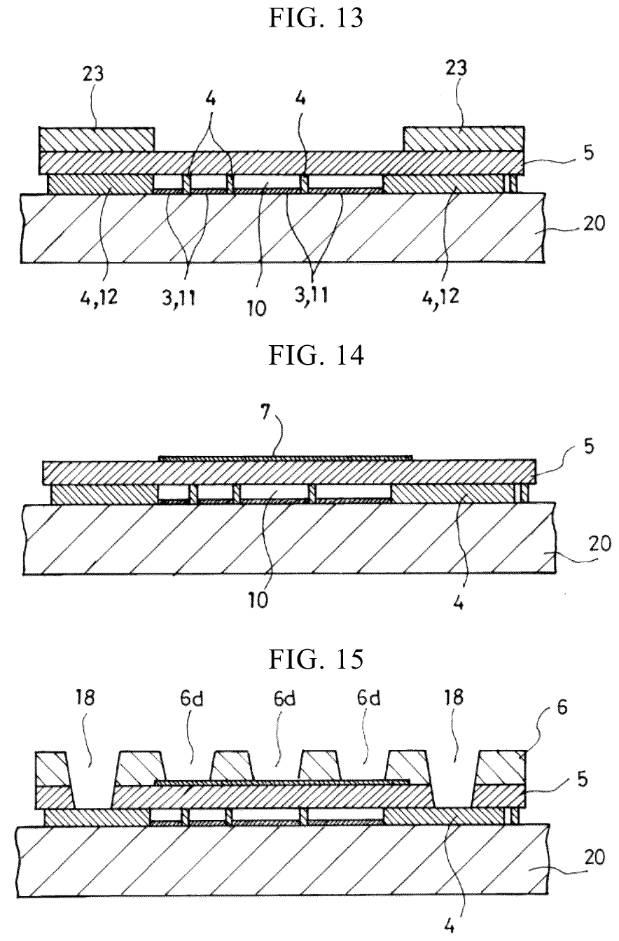

Next, a resist 23 for forming the metal layer within the roof 7 is formed on the first roof portion 5 formed in the third step, and the metal layer within the roof 7 is formed by lift-off using the resist 23 (fourth step/FIGS. 13 to 14).

Then, the resist 23 formed in the fourth step is removed (fifth step/FIG. 14).

The second roof portion 6 is then formed on the first roof portion 5.

The second roof portion 6 can be formed by laminating a resin-made planar body (film) on the first roof portion 5 and integrating them. Alternatively, the second roof portion 6 may be formed by applying the resin onto the first roof portion 5.

After forming the resin layer to be the second roof portion 6 on the first roof portion 5 in this way, a resist (drawing is omitted) for forming the connecting passing hole 18 and the heat dissipating passing hole 6d is formed thereon. With using the resist, the connecting passing hole 6c and the heat dissipating passing hole 6d are formed by removing a portion of the resin layer to be the first roof portion 5 and the second roof portion 6 by a chemical treatment at a forming region of the connecting passing hole 18, and by removing a portion of the resin layer to be the second roof portion 6 by a chemical treatment at a portion at a forming region of the heat dissipating passing hole 6d (seventh step/FIG. 15).

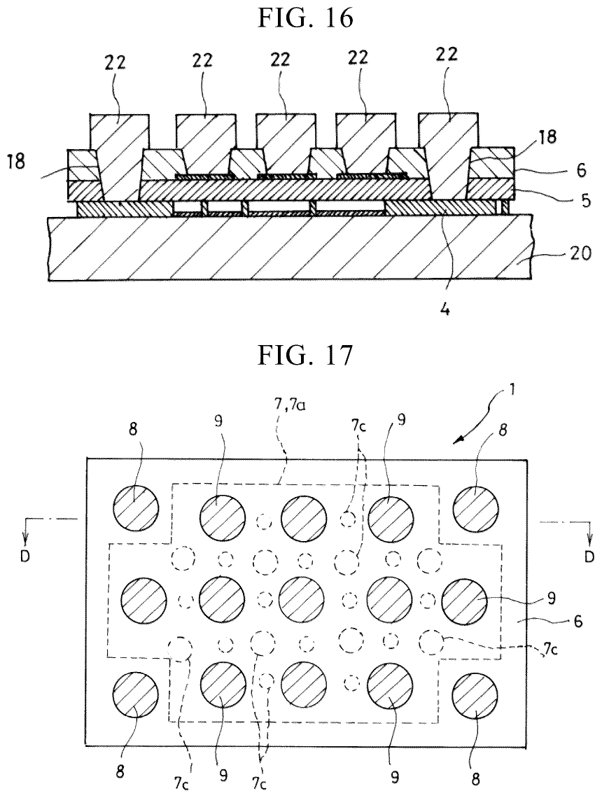

Next, after the resist formed in the seventh step is removed, the connecting passing hole 18 and the heat dissipating passing hole 6d are coated and filled with the cream-solder 22 typically by a printer (eighth step/FIG. 16).

Reflow process after the eighth step forms the external connecting solder bumps 8 and the heat dissipating solder bump 9 having a height protruding from the outer surface of the second roof portion 6.

Thereafter, dicing is performed on the wafer 20 to generate the acoustic wave device 1 including the plurality of structures from the wafer 20.

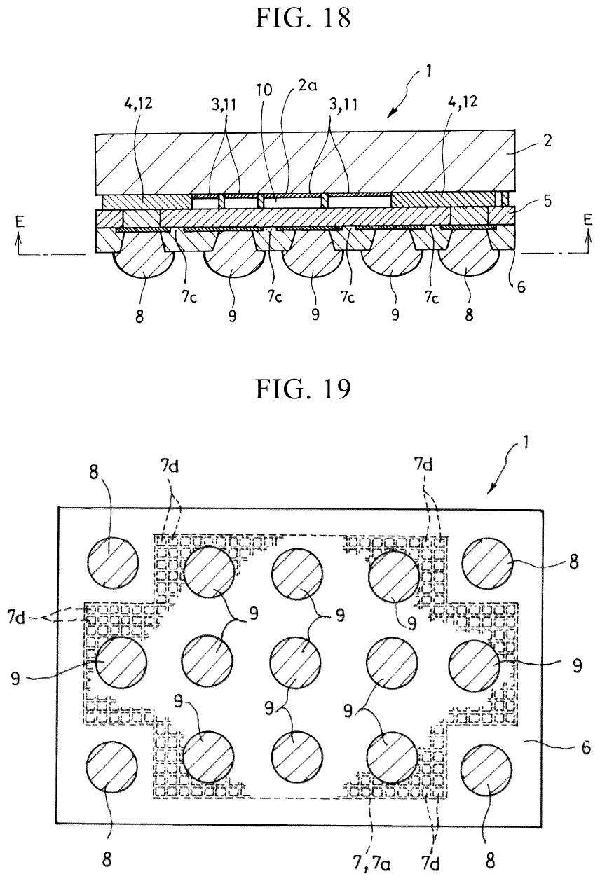

FIG. 17 and FIG. 18 show another example (as the third example) in which the metal layer within the roof 7 is formed to have a plurality of through-hole 7c.

This enables fixing the second roof portion 6 to the first roof portion 5 by inserting the resin constituting the second roof portion 6 into the through-hole 7c at the forming region of the through-hole 7c.

FIG. 19 is a cross-sectional view of a fourth example of the acoustic wave device in which a part of the configuration is different from that of the first example, and the fourth example is shown from the same direction as that of FIG. 3. FIG. 19 shows the metal layer within the roof 7 has a form of mesh.

This enables fixing the second roof portion 6 to the first roof portion 5 by inserting the resin constituting the second roof portion 6 into a mesh openings 7d at the mesh openings of the metal layer within the roof 7 having the form of mesh.

It should be noted that, of course, the present disclosure is not limited to the embodiments described above, but includes the embodiments that can achieve the purpose of the present disclosure.

What is claimed is:

1. An acoustic wave device comprising:
a device chip;
a first metal pattern formed on one surface of the device chip and comprising a pattern configured to form a resonator;
a second metal pattern formed on the one surface of the device chip so as to comprise a predetermined thickness larger than a thickness of the first metal pattern at any position and comprising a pattern comprising a signal input/output terminal, a wiring connecting the signal input/output terminal and the resonator, a wiring connecting a plurality of resonators comprising the resonator and a ground wiring;
a first roof portion made of resin formed on the second metal pattern and cooperating with the one surface of the device chip and the second metal pattern to form a sealed space of the resonator;
a metal layer within the roof formed on the first roof portion,
a second roof portion made of resin formed on the first roof portion so as to position a portion of the metal layer within the roof between the first roof portion and the second roof portion,
two or more heat dissipation solder bumps formed by using a heat dissipation passage hole passing through the second roof portion and including an inner end portion joined to the metal layer within the roof and an outer end portion protruding from the second roof portion.

2. The acoustic wave device according to claim 1, wherein the first roof portion includes a resin that is non-photosensitive and a higher thermal conductivity than a thermal conductivity of the second roof portion.

3. The acoustic wave device according to claim 1, wherein a thickness of the first roof portion is smaller than a thickness of the second roof portion.

4. The acoustic wave device according to claim 1, wherein the ground wiring is arranged so as to surround the first metal pattern, the signal input/output terminal, the wiring connecting the signal input/output terminal and the resonator, and the wiring connecting the plurality of resonators.

5. The acoustic wave device according to claim 1, wherein a portion of the metal layer within the roof is electrically connected to the signal input/output terminal through a via penetrating the first roof portion, and the acoustic wave device further comprises an external connecting solder bump formed by a connecting passing hole passing through the second roof portion and comprising an inner end portion joined to the portion of the metal layer within the roof and an outer end portion protruding from the second roof portion.

6. The acoustic wave device according to claim 1, further comprising:
an external connecting solder bump formed by a connecting passing hole passing through the first roof portion and the second roof portion and comprising an inner end portion joined to the signal input/output terminal and an outer end portion protruding from the second roof portion.

7. The acoustic wave device according to claim 1, wherein the metal layer within the roof is formed to have a plurality of through holes.

8. The acoustic wave device according to claim 1, wherein the metal layer within the roof has a form of mesh.
